(19) United States
(12) Patent Application Publication
(10) Pub. No.: US 2004/0009619 A1
(43) Pub. Date: Jan. 15, 2004

(54) Automatic fluid scanner

(75) Inventors: Liviu Marian, Danbury, CT (US); William J. Fenton, Danbury, CT (US)

Correspondence Address: MORGAN LEWIS & BOCKIUS LLP, 1111 PENNSYLVANIA AVENUE NW, WASHINGTON, DC, 20004, US

(73) Assignee: Interlab, Inc.

(21) Appl. No.: 10/611,059

(22) Filed: Jul. 2, 2003

Related U.S. Application Data
(60) Provisional application No. 60/393,676, filed on Jul. 3, 2002.

(51) Int. Cl. H01L 21/306

(52) U.S. Cl. 438/14; 156/345.31

(57) ABSTRACT

A method and apparatus for using a robot for handling and processing of a semiconductor wafer. In particular, the robot is used to transfer wafers from a variety of wafers holding devices to a number of processing locations. After the wafer is placed in position, the robot places the vacuum wand in a temporary parking position and engages a different tool to process the wafer. In subsequent stages, yet another tool is engaged by the same robot to handle the chemistry used in the process.

### FIELD OF THE INVENTION

The invention relates generally to silicon wafer processing and, more specifically, to the analysis of impurities in silicon wafers.

### DESCRIPTION OF RELATED ART

Integrated circuits are manufactured starting with blank silicon wafers that are put through many processing steps. The quality of the blank silicon wafer is an important determining factor in the performance of semiconductor devices in the final product. Metal oxide silicon field effect transistors (MOSFETs), which depend upon a thin silicon oxide gate insulator, are often used in integrated circuits.

The reliability of present-day high density technology depends on a lack of metallic impurities within the wafer surface, as well as a lack of impurities in the chemicals used to grow layers; therefore, silicon wafer manufacturers are in need of quality control of the starting material to provide reliable substrates. Maeda, et al., U.S. Pat. No. 4,990,459 developed a vapor phase decomposition (VPD) technique. The VPD technique extracts and concentrates trace levels of metallic contaminants from the surface of a test wafer by decomposing a layer of silicon oxide with HF vapors. The residue, which contains non volatile impurities, is then collected in a small droplet of a suitable acid such as hydrofluoric acid. The droplet is systematically moved across the entire wafer surface so that all the residue is collected. The recovered droplet is then analyzed by well known analytical methods.

In a patent by Petvai, et. al. U.S. Pat. No. 6,273,992, the manual sample collection technique was improved by automating the movement of the collection droplet. “An inert carrier is used to contain the droplet as well as increase the contact area of the droplet. Not only is the reliability and reproducibility of sample collection improved by this apparatus, but the cycle time and the risk of external contamination are greatly reduced. The wafer is mounted on a table having a programmable rotation. The apparatus provides a robotic arm which transports the wafers from a cassette to a VPD chamber where HF vapors decompose the silicon oxide layer. The wafer then passes to the droplet collection station where the sample is collected by a droplet on a pre-loaded sample carrier delivered from a carousel. The entire apparatus operates in an internal class 1 environment.”

The above mentioned method and apparatus have the disadvantage of mechanical and electrical complexity. The handling of the wafer, handling of chemistry, and the scanning itself is performed by separate devices. The present invention eliminates the complex and difficult mechanical, electrical and software interface between the aforementioned devices.

### OBJECTS AND SUMMARY OF THE INVENTION

It is an object of the invention to provide improved methods and systems for handling a silicon wafer from a cassette to a VPD chamber, and for placing a chemical droplet on the silicon wafer using the same robot.

It is another object of this invention to provide a method and apparatus for scanning the wafer using the same robot used for handling, thus eliminating the need for a separate, complex scanning device.

It is another object of this invention to provide a method and apparatus for retrieving the droplet after the scan and delivering it to a variety of locations (vial, drying substrate or analysis tool) using the same robot, thus eliminating the need for a separate, complex retrieving device.

It is yet another object of this invention to provide a method and apparatus for controlling all supporting devices (sensors, pump, automatic doors, etc) by the robot controller, thus eliminating the need of interfacing two or more controllers.

### BRIEF DESCRIPTION OF THE FIGURES

FIG. 1 is a front view of a first embodiment of an apparatus for analyzing impurities in a silicon wafer;

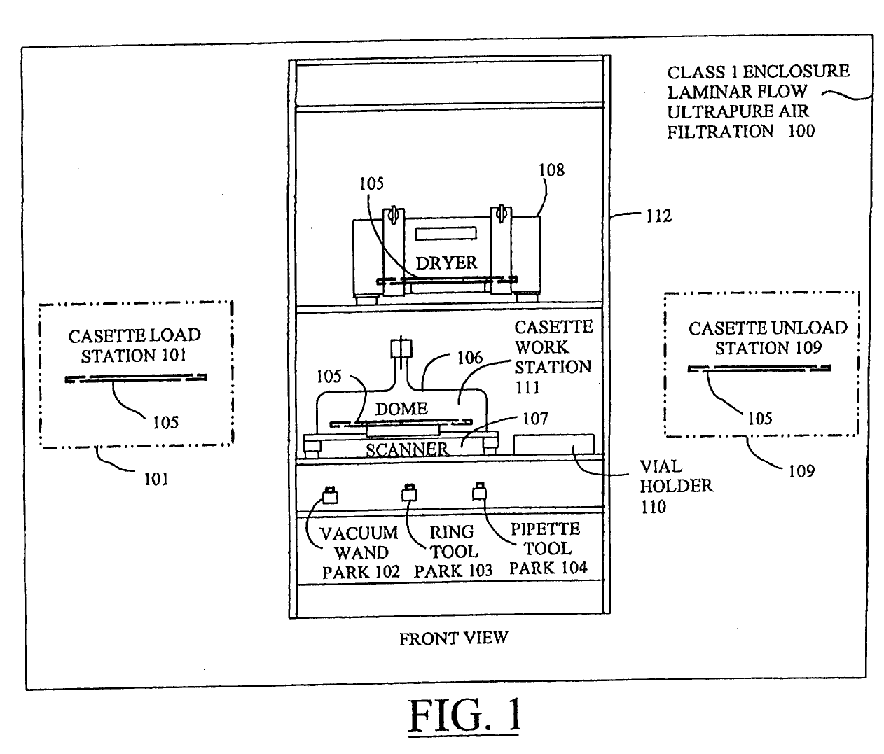

FIG. 2 is a side view of the apparatus shown in FIG. 1;

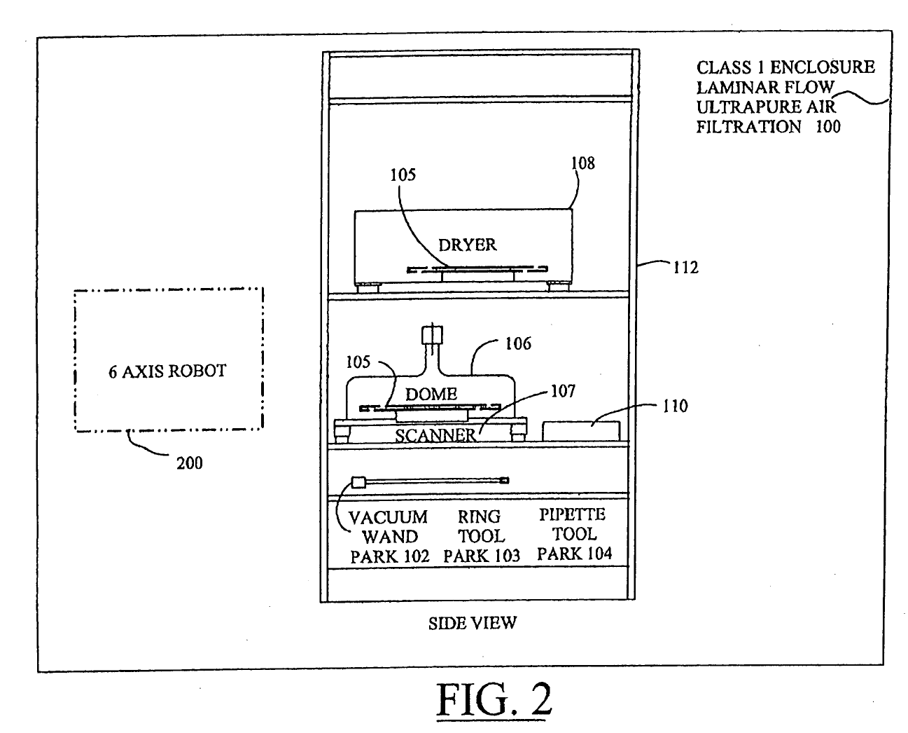

FIG. 3 is a top view of the apparatus shown in FIG. 1;

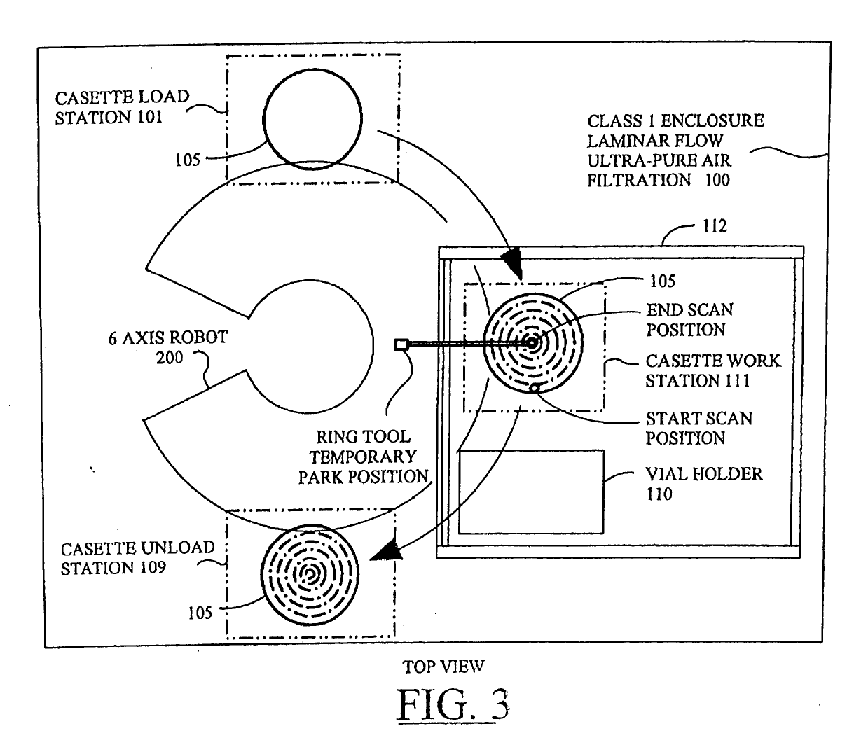

FIG. 4 is a diagrammatic representation of three tools used by the robot shown in FIGS. 1, 2, and 3; and

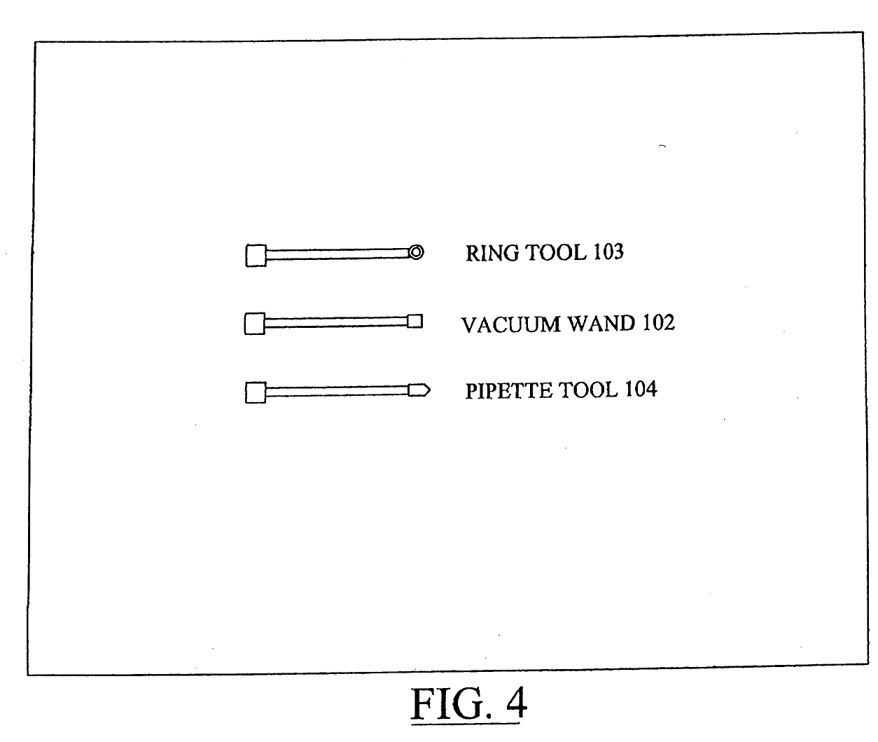

FIG. 5 is a top view of a second embodiment of an apparatus for analyzing impurities in a silicon wafer.

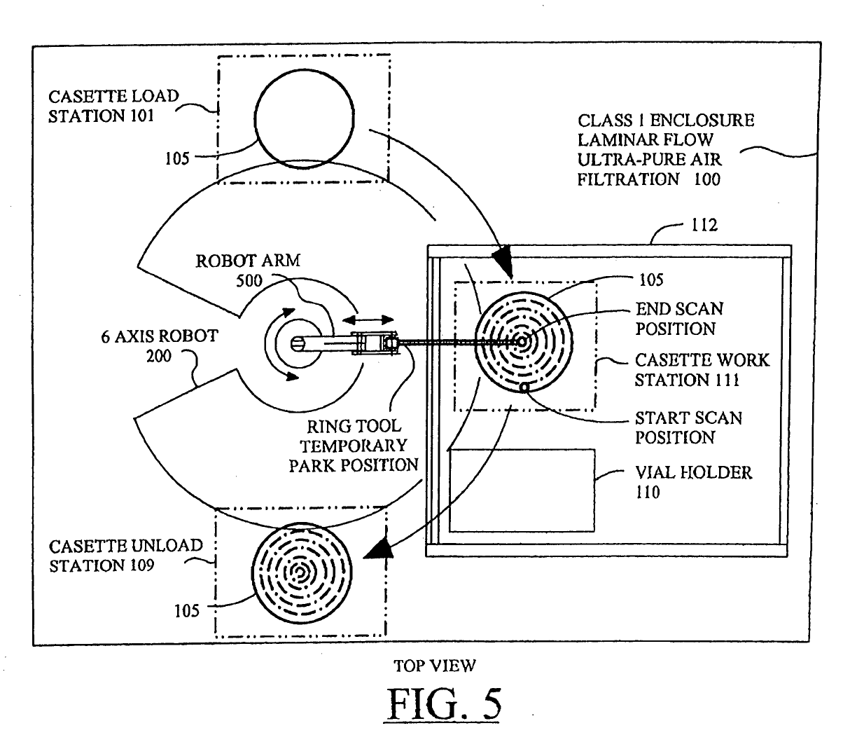

### DETAILED DESCRIPTION OF THE PREFERRED EMBODIMENTS

A robot (for example, Yaskawa Motoman-SV035) is located such that its envelope reaches the load cassette, VPD chamber, scanning platform, dryer, analytical tool and unload cassette.

All of the aforementioned components are placed under a class 1 flow hood. The robot arm is able to engage three tools: a vacuum wand used to move wafers, a pipette holder used for handling chemical droplets and a scanning ring used to move the droplet in a controlled pattern on the surface of the wafer. The tool changing apparatus is clean room and corrosive environment compatible.

The robot engages vacuum wand tool, picks up a wafer from the load cassette and places it in the VPD chamber.

After the VPD process is completed and the chamber is exhausted the chamber is opened (or the dome raised, depending on design).

If scanning is to take place on the scanning platform, the robot will transfer wafer from chamber to scanner platform. If the scanning is to take place in the chamber skip to next step.

The robot parks and disengages the vacuum wand and then engages pipette tool. The pipette tool is attached to a metering pump through a flexible tube.

A precise amount of chemistry (i.e., a chemical droplet) is retrieved from a holding vial. With the pump direction reversed, the chemistry is placed on the wafer.

The robot disengages and parks the pipette tool. After that, it engages the scanning ring tool. The invention takes advantage of the very high precision of the repetitive position accuracy of the robot (for example, 0.004 inch). This allows the elimination of several stepper motors, encoders and the corresponding mechanics and controls used in previous designs. The scanner, which used to be a complex device, becomes a simple, cost-effective platform. The lack of moving parts also has the advantage of eliminating several moving parts that could generate contaminating particles. Another advantage is a more laminar flow across the wafer. Yet another advantage is that construction materials can be limited to the most advantageous ones.

The robot can be programmed for any number of scanning patterns, for example: full scan, edge, exclusion, annulus, pie shape. The level of automation allows integration with the semiconductor.

In previous designs, the distance between the scanning ring and the surface of the wafer was set by mechanical devices, more specifically by adjusting the weight applied to the scanning ring. The balance between the weight and the pressure generated by the surface tension of the droplet would establish the distance. The tuning process is a trial-and-error technique. The advantage of using a robot for scanning is that, once the robot is calibrated, the gap is fully adjustable by the software.

After the scanning is completed, the robot parks the scanning ring tool in a temporary position. The position allows the ring to remain in the same position. The robot then picks up the pipette tool and retrieves the droplet through the ring. The precision of the robot allows retrieval of substantially all of the chemistry (i.e., the droplet). Again, the advantage of using a robot for pipette pick-up is that once the robot is calibrated, the pick-up position is fully adjustable in the software. The adjustment of a separate controller is eliminated.

The droplet is deposited on a separate substrate for drying, or is deposited in a vial or directly into an analytical tool. The reach of the robot and the ease of setup (software) allow placing the droplet in a variety of places, depending on the specific application. This constitutes another advantage compared to the limited reach of the droplet handling devices of the previous designs.

The pipette tool is parked. In one embodiment the ring tool is parked in a cascade rinse position where the potential contamination from the last wafer scanned is removed.

The robot engages the vacuum wand and transfers the scanned wafer to the unload cassette.

The above describes only one of the possible embodiments. The usage of a robot with a wide range of motions, large envelope and versatile software allows a variety of setups and/or integration with production lines or analysis equipment.

What is claimed:

1. An apparatus comprising:
a. a laminar flow enclosure,
b. ultrapure air filtration for said enclosure, class, 1, Federal Standard 209D,
c. a multiple axis robot,
d. arm of the robot including a tool changing device,
e. a removable vacuum wand tool,
f. a removable pipette holder tool,
g. a removable scanning ring holder ring,
h. a cascade rinsing position for scanning ring,
i. a VPD chamber,
j. a wafer scanning platform,
k. a wafer dryer,
l. a parking position for removable vacuum wand tool,
m. aparking position for the removable pipette holder tool, and
n. a parking position for the removable scanning ring holder tool.

2. The apparatus of claim 1, wherein said apparatus contains automatic, clean room compatible doors for the VDP chamber and for the wafer dryer.

3. The tool apparatus of claim 1, wherein said tool changer engages and disengages tool without the intervention of an operator.

4. The apparatus device of claim 1, wherein said tool changer is clean room compatible.

5. The apparatus device of claim 1, wherein said tool changer is acid and/or corrosive environment compatible.

6. The apparatus of claim 1, wherein said robot with said pipette holder is able to access an analytical tool.

7. The apparatus of claim 1, wherein all supporting devices are controlled by the central hardware and software control of the robot.

8. The apparatus of claim 1, wherein the scanning can be done in the VPD chamber OR on scanning platform as desired.

9. A method of wafer processing including the following steps:
a. engaging a vacuum wand tool,
b. transferring a wafer to the VPD chamber,
c. if scanning is to take place on the scanning platform, transferring the wafer from a chamber to a scanner platform,
d. disengaging and parking the vacuum wand,
e. engaging a pipette tool,
f. filling the pipette 1001 with a scanning fluid,
g. placing a droplet on the wafer which is on the scanner platform,
h. disengaging and parking the pipette tool,
i. engaging the scanning ring tool,
j. scanning the wafer,
k. disengaging and parking the scanning ring tool,
l. engaging the pipette tool,
m. retrieving the droplet from the wafer,
n. either placing the droplet in a testing vial, or analytical tool, or placing the droplet on a drying substrate,
o. disengaging and parking the pipette tool,
p. engaging the vacuum wand,
q. unloading the wafer, and
r. retrieving the drying substrate from the dryer.

10. The method of claim 9 using various scanning patterns programmed into the robot controls and selectable by the operator through a Graphic User Interface.

11. The method of claim 9 having more than one wafer during the steps of processing and/or transporting.
